(19) United States
(12) Patent Application Publication
(10) Pub. No.: US 2024/0147769 A1
(43) Pub. Date: May 2, 2024

(54) DISPLAY PANEL

(71) Applicant: Samsung Display Co., Ltd., Yongin-Si (KR)

(72) Inventor: Junhee Lee, Yongin-si (KR)

(21) Appl. No.: 18/381,174

(22) Filed: Oct. 18, 2023

(30) Foreign Application Priority Data
Oct. 26, 2022 (KR) 10-2022-0139669

(51) Int. Cl. H10K 59/122; H10K 59/38; H10K 59/40; H10K 59/80

(52) U.S. Cl. CPC H10K 59/122; H10K 59/38; H10K 59/40; H10K 59/873; H10K 59/8792; H10K 2102/351

(57) ABSTRACT

Provided is a display panel including a substrate, a pixel electrode on the substrate, a pixel-defining layer including an opening corresponding to a portion of the pixel electrode and in which a groove is defined around the pixel electrode, a color filter arranged to correspond to the opening of the pixel-defining layer, and a black matrix arranged to correspond to the pixel-defining layer.

### CROSS-REFERENCE TO RELATED APPLICATION

This application is based on and claims priority under 35 U.S.C. § 119 to Korean Patent Application No. 10-2022-0139669, filed on Oct. 26, 2022, in the Korean Intellectual Property Office, the disclosure of which is incorporated by reference herein in its entirety.

### BACKGROUND

### 1. Field

The present disclosure generally relates to a display panel and a display device including the same. More particularly, the present disclosure relates to a display panel in which a separator formed at a pixel-defining layer is not exposed outside a black matrix and a display device including the same.

### 2. Description of the Related Art

Recently, purposes of display devices have diversified. Also, as thicknesses and weights of display devices are decreasing, the range of use thereof is becoming wider.

As display devices are variously used, there may be various methods for designing the shape of display devices, and functions that may be grafted or linked to the display devices are increasing.

### SUMMARY

One or more embodiments include a display device in which display quality is improved. However, such an objective is only an example and the scope of the disclosure is not limited thereby.

Additional aspects will be set forth in part in the description which follows and, in part, will be apparent from the description, or may be learned by practice of the presented embodiments of the disclosure.

According to one or more embodiments, a display panel includes a substrate, a pixel electrode disposed on the substrate, a pixel-defining layer disposed between the pixel electrodes, wherein an opening corresponding to a portion of the pixel electrode may be defined in the pixel-defining layer and at lease one groove is defined around the pixel electrode, a color filter arranged to correspond to the opening of the pixel-defining layer, and a black matrix arranged to correspond to the pixel-defining layer, wherein the groove in the pixel-defining layer is located within a width of the black matrix.

The display panel may further include an opposing electrode facing the pixel electrode, and an intermediate layer disposed between the pixel electrode and the opposing electrode, wherein a hole corresponding to the groove in the pixel-defining layer may be defined in the opposing electrode and the intermediate layer.

The intermediate layer may include an organic functional layer and a charge generation layer.

An opening corresponding to the opening of the pixel-defining layer may be defined in the black matrix, wherein an area of the opening of the black matrix may be greater than an area of the opening of the pixel-defining layer.

There may be a plurality of grooves in the pixel-defining layer, and the plurality of grooves may be arranged in parallel to each other.

There may be a plurality of grooves in the pixel-defining layer, and the plurality of grooves may be spaced apart from each other along an edge of the pixel electrode.

The groove in the pixel-defining layer may extend along an edge of the pixel electrode and surround a portion of the pixel electrode.

The display panel may further include an upper layer disposed on the opposing electrode, wherein a hole corresponding to the groove in the pixel-defining layer may be defined in the upper layer.

The display panel may further include a spacer disposed on the pixel-defining layer, wherein the groove may not be located in the pixel-defining layer where the spacer is disposed.

The display panel may further include a thin-film encapsulation layer disposed between the opposing electrode and the color filter, wherein the thin-film encapsulation layer may cover the groove in the pixel-defining layer.

The display panel may further include a touch screen disposed between the thin-film encapsulation layer and the color filter, wherein a touch electrode of the touch screen layer may be covered by the black matrix.

According to one or more embodiments, a display panel includes a substrate including a display area, in which an emission area and a non-emission area surrounding the emission area are defined, a pixel-defining layer arranged to correspond to the non-emission area, in which a groove is defined, wherein a first opening corresponding to the emission area may be defined in the pixel-defining layer, a black matrix arranged to corresponding to the non-emission area, wherein a second opening corresponding to the emission area may be defined in the black matrix and may have a greater area than the first opening, and arranged to corresponding to the non-emission area, and a color filter arranged in the second opening of the black matrix, wherein an entirety of the black matrix completely covers the groove in the pixel-defining layer.

The display panel may further include a plurality of pixel electrodes, each of the plurality of pixel electrodes arranged to a corresponding emission area, an opposing electrode facing the plurality of pixel electrodes, and an intermediate layer between the plurality of pixel electrodes and the opposing electrode, wherein the opposing electrode and the intermediate layer may each include a hole corresponding to the groove in the pixel-defining layer.

The intermediate layer may include an organic functional layer and a charge generation layer.

There may be a plurality of grooves in the pixel-defining layer, and the plurality of grooves may be arranged in parallel to each other.

There may be a plurality of grooves in the pixel-defining layer, and the plurality of grooves may be spaced apart from each other along edges of the plurality of pixel electrodes.

The groove in the pixel-defining layer may extend along edges of the plurality of pixel electrodes and surround portions of the plurality of pixel electrodes.

The display panel may further include an upper layer disposed on the opposing electrode, wherein the upper layer may include a hole corresponding to the groove in the pixel-defining layer.

The display panel may further include a spacer disposed on the pixel-defining layer, wherein the groove may not be located in the pixel-defining layer where the spacer is disposed.

The display panel may further include a thin-film encapsulation layer disposed between the opposing electrode and the color filter, wherein the thin-film encapsulation layer may cover the groove in the pixel-defining layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a display panel according to an embodiment;

FIG. 2 is a plan view of a portion of a display area, according to an embodiment;

FIG. 3 is a cross-sectional view of the display area taken along line I-I′ of FIG. 2;

FIG. 4 is an enlarged plan view for describing a relationship between a pixel-defining layer and a black matrix;

FIG. 5 is a plan view of a portion of a display area, according to an embodiment;

FIG. 6 is a cross-sectional view of the display area taken along line II-II′ of FIG. 5;

FIGS. 7 and 8 are plan views of portions of display areas, according to embodiments;

FIG. 9 is a cross-sectional view of the display area taken along line III-Ill′ of FIG. 8;

FIG. 10 is a view of a first pixel of FIG. 9;

FIGS. 11 and 12 are plan views of portions of display areas, according to embodiments;

FIG. 13 is a cross-sectional view of the display area taken along line IV-IV′ of FIG. 12; and

FIGS. 14 and 15 are views showing arrangements of emission areas of a plurality of pixels, according to embodiments.

### DETAILED DESCRIPTION

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like elements and redundant descriptions thereof will be omitted.

As used herein, the term “and/or” includes any and all combinations of one or more of the associated listed items.

It will be understood that when a layer, region, or element is referred to as being “formed on,” another layer, region, or element, it can be directly or indirectly formed on the other layer, region, or element. That is, for example, intervening layers, regions, or elements may be present. Sizes of elements in the drawings may be exaggerated for convenience of explanation. In other words, because sizes and thicknesses of elements in the drawings are arbitrarily illustrated for convenience of explanation, the disclosure is not necessarily limited thereto.

In the following embodiments, “on a plane” denotes that a target portion is viewed from above and “on a cross section” means that a vertically cut cross section of a target portion is viewed from the side. According to embodiments, when a first element “overlaps” a second element, the first element may be located on or below the second element.

According to embodiments, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

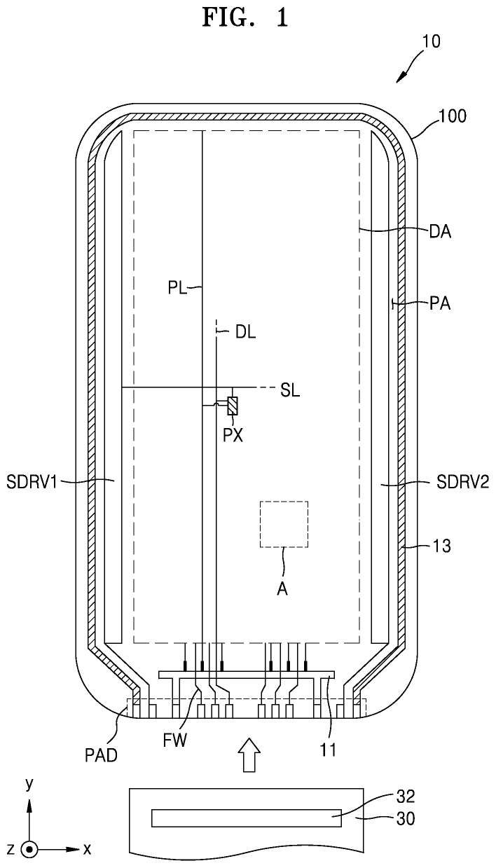

FIG. 1 is a plan view of a display panel 10 according to an embodiment.

The display panel 10 may be a light-emitting display panel including a light-emitting element. For example, the display panel 10 may be an organic light-emitting display panel using an organic light-emitting diode (OLED) including an organic emission layer, a micro-LED display panel using a micro-LED, a quantum dot light-emitting display panel using a quantum dot LED including a quantum dot emission layer, or an inorganic light-emitting display panel using an inorganic LED including an organic semiconductor.

A display device may include the display panel 10 and a cover window (not shown) protecting the display panel 10 may be further disposed on the display panel 10.

The display panel 10 may include a display area DA for realizing an image and a peripheral area PA outside the display area DA. The peripheral area PA may be a type of non-display area where display elements are not arranged. The display area DA may be entirely surrounded by the peripheral area PA. Various elements included in the display panel 10 may be arranged on a substrate 100. Accordingly, the substrate 100 may include the display area DA and the peripheral area PA.

A plurality of pixels PX may be arranged in the display area DA. The pixel PX may include a display element. The display element may be connected to a pixel circuit driving the pixel PX. According to an embodiment, the display element may be an organic LED. Each pixel PX may be configured to emit, for example, red, green, blue, or white light through an OLED. The plurality of pixels PX may include a first pixel emitting a first color, a second pixel emitting a second color, and a third pixel emitting a third color. For example, the first pixel may be a red pixel, the second pixel may be a green pixel, and the third pixel may be a blue pixel. According to an embodiment, the plurality of pixels PX may further include a white pixel emitting white color.

Various wires configured to transmit an electric signal to be applied to the display area DA, external circuits electrically connected to the pixel circuits, and pads to which a printed circuit board or a driver integrated circuit (IC) chip is attached may be located in the peripheral area PA. For example, a first scan driving circuit SDRV1, a second scan driving circuit SDRV2, a terminal portion PAD, a driving voltage supply line 11, and a common voltage supply line 13 may be arranged in the peripheral area PA.

The first scan driving circuit SDRV1 may be configured to apply a scan signal that is a gate control signal to each pixel circuit through a scan line SL. The second scan driving circuit SDRV2 may be located on an opposite side of the first scan driving circuit SDRV1, based on the display area DA, and may be approximately parallel to the first scan driving circuit SDRV1. Some of the pixel circuits of the pixels PX of the display area DA may be electrically connected to the first scan driving circuit SDRV1 and the remaining pixel circuits may be electrically connected to the second scan driving circuit SDRV2. The second scan driving circuit SDRV2 may be omitted.

The terminal portion PAD may be arranged at one side of the substrate 100. The terminal portion PAD may not be covered by an insulating layer, but may be exposed to be connected to a display circuit board 30. A display driving unit 32 may be arranged in the display circuit board 30. The display driving unit 32 may be formed in a form of one or more IC chips and mounted on the display circuit board 30.

The display driving unit 32 may be configured to generate a control signal transmitted to the first scan driving circuit SDRV1 and the second scan driving circuit SDRV2. The display driving unit 32 may be configured to generate data signals, and the data signals may be transmitted to the pixel circuits of the pixels PX through fan-out lines FW and data lines DL connected to the fan-out lines FW.

The display driving unit 32 may be configured to supply a first power voltage ELVDD to the driving voltage supply line 11 and supply a second power voltage ELVSS to the common voltage supply line 13. The first power voltage ELVDD may be applied to the pixel circuits of the pixels PX through a first power voltage line PL connected to the driving voltage supply line 11, and the second power voltage ELVSS may be applied to an opposing electrode of the display element through the common voltage supply line 13.

The driving voltage supply line 11 may be connected to the terminal portion PAD and may extend in an x-axis direction from below the display area DA. The common voltage supply line 13 may be connected to the terminal portion PAD and may partially surround the display area DA by having a loop shape in which one side is opened.

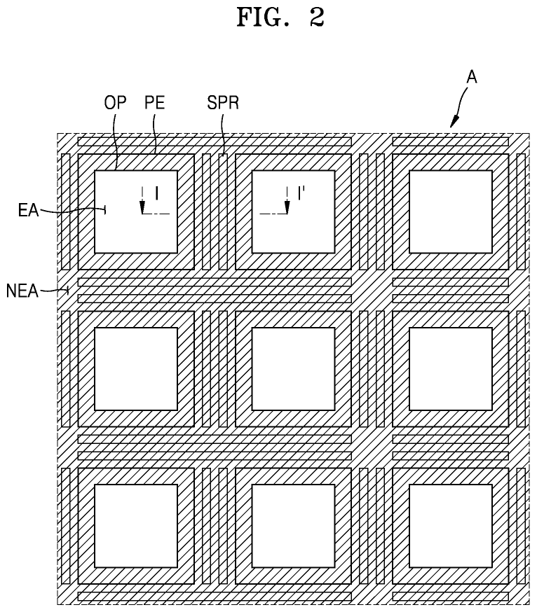

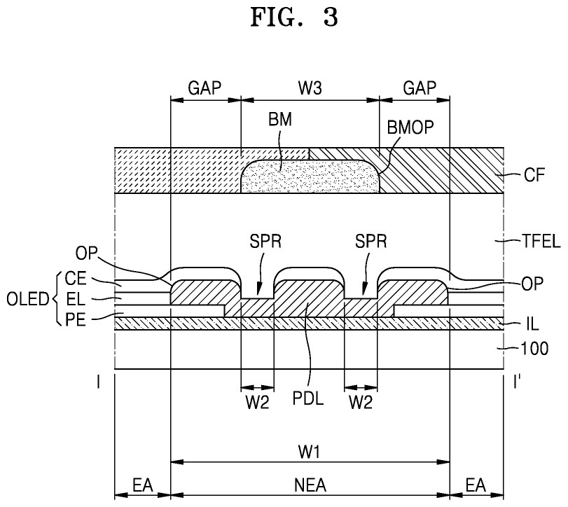

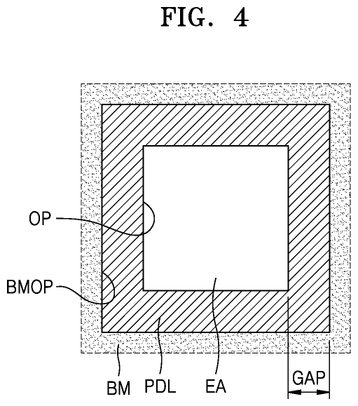

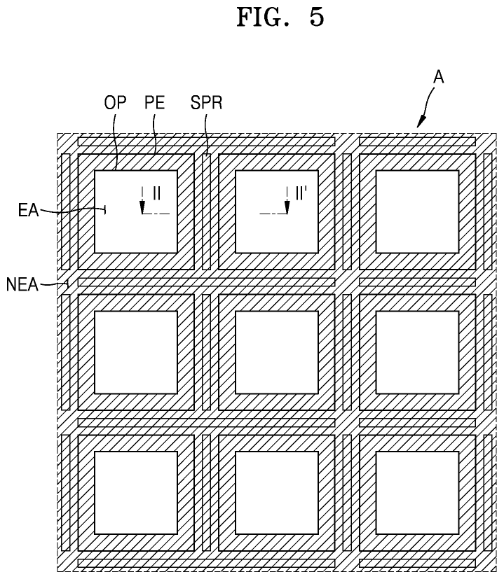

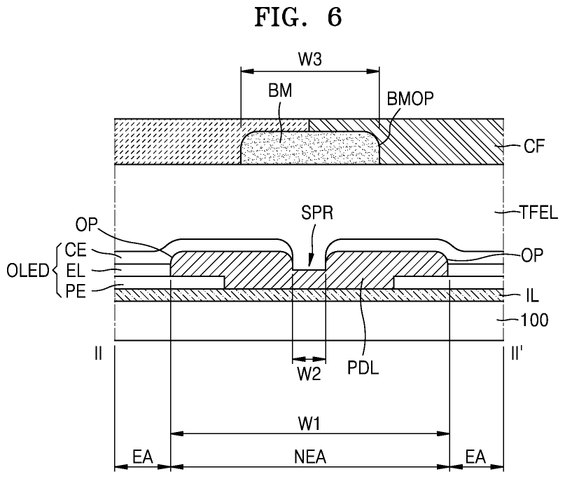

FIG. 2 is a plan view of a portion of the display area DA, according to an embodiment. FIG. 3 is a cross-sectional view of the display area DA taken along line I-I′ of FIG. 2. FIG. 4 is an enlarged plan view for describing a relationship between a pixel-defining layer PDL and a black matrix BM. FIG. 5 is a plan view of a portion of the display area DA, according to an embodiment. FIG. 6 is a cross-sectional view of the display area DA taken along line II-II′ of FIG. 5. FIGS. 2 and 5 each illustrate a region A of the display area DA of FIG. 1.

A plurality of organic light-emitting diodes OLED may be arranged on the substrate 100. The organic light-emitting diode OLED may include a pixel electrode PE, an opposing electrode CE, and an emission layer EL between the pixel electrode PE and the opposing electrode CE.

Referring to FIG. 2, the display area DA of the substrate 100 may include an emission area EA and a non-emission area NEA surrounding the emission area EA. The emission area EA is an area where the emission layer EL of the organic light-emitting diode OLED is arranged. As shown in FIG. 3, the emission area EA may be defined by an opening OP of the pixel-defining layer PDL.

The pixel electrodes PE may be arranged on the substrate 100, and the pixel-defining layer PDL may be provided between the pixel electrodes PE. The opening OP corresponding to a portion of the pixel electrode PE may be defined in the pixel-defining layer PDL. The emission layer EL may be arranged in the opening OP of the pixel-defining layer PDL, and the opposing electrode CE may be disposed on the emission layer EL. The opposing electrode CE may be arranged on an upper surface of the pixel-defining layer PDL.

A groove SPR may be defined in the pixel-defining layer PDL between the pixel electrodes PE. According to an embodiment, two grooves SPR may be defined in the pixel-defining layer PDL between the pixel electrodes PE. The pixel-defining layer PDL between the pixel electrodes PE may have a first width W1. The groove SPR may have a second width W2, have a straight-line shape extending in the x-axis direction or y-axis direction, and be spaced apart from the neighboring groove SPR. The two grooves SPR may be parallel to each other. The groove SPR in the x-axis direction and the groove SPR in the y-axis direction may not cross each other but may be spaced apart from each other. A width of the pixel-defining layer PDL may correspond to an interval between the pixel electrodes PE. A width of the groove SPR may be an interval between two sides of the groove SPR in a direction perpendicular to an extending direction of the groove SPR.

The groove SPR may be a concave portion dug to a certain depth in a z-axis direction by removing a portion of the pixel-defining layer PDL. According to an embodiment, as shown in FIG. 3, the groove SPR may be formed by removing the portion of the pixel-defining layer PDL through etching, after the opposing electrode CE is formed. At this time, a portion of the opposing electrode CE disposed on the pixel-defining layer PDL is removed together, and thus the opposing electrode CE may include a hole corresponding to the groove SPR. A cross-section of the groove SPR may have U shape, a triangular shape, a quadrangular shape, a trapezoidal shape, or a polygonal shape. According to another embodiment, the groove SPR may be a hole penetrating the pixel-defining layer PDL.

A thin-film encapsulation layer TFEL may be disposed on the organic light-emitting diode OLED. An optical functional layer including the black matrix BM and color filters CF may be disposed on the thin-film encapsulation layer TFEL. A polarizing plate or a polarizing film may be omitted from the display device by the optical functional layer including the color filters CF having an external light blocking function. The display device including the optical functional layer of the color filter CF and black matrix BM may have a largely reduced thickness compared to a display device including a polarizing plate. The optical functional layer may further include an overcoated layer (not shown) on the color filters CF.

The color filter CF may be arranged to correspond at least to the emission area EA, considering a color of light emitted from each of the pixels PX of the display panel 10. The color filter CF may have a red, green, or blue color depending on a color of light emitted from the organic light-emitting diode OLED. The black matrix BM may surround the emission area EA and be arranged to correspond to the non-emission area NEA. An opening BMOP corresponding to the emission area EA may be defined in the black matrix BM. A size (area) of the opening BMOP of the black matrix BM may be greater than a size (area) of the opening OP of the pixel-defining layer PDL or a size (area) of the emission area EA. An edge of the black matrix BM and an edge of the pixel-defining layer PDL may be spaced apart from each other by a gap GAP. The black matrix BM between the adjacent pixel electrodes PE may have a third width W3. The black matrix BM may overlap the grooves SPR of the pixel-defining layer PDL, and the grooves SPR may be provided within the third width W3 of the black matrix BM. The third width W3 of the black matrix BM may be greater than a sum of the second widths W2 of the grooves SPR covered by the black matrix BM. A width of the black matrix BM may correspond to an interval between the pixel electrodes PE.

When the grooves SPR of the pixel-defining layer PDL deviate from the third width W3 of the black matrix BM, a color separation phenomenon may occur when external light is introduced thereto. According to an embodiment, the black matrix BM completely covers the grooves SPR of the pixel-defining layer PDL such that the grooves SPR of the pixel-defining layer PDL do not deviate from the third width W3 of the black matrix BM, thereby reducing the color separation phenomenon.

In FIG. 3, the edge of the black matrix BM and an external edge of each groove SPR match each other, but according to another embodiment, the external edge of each groove SPR may be located more inside than the edge of the black matrix BM.

The number of grooves SPR between the pixel electrodes PE may be determined according to resolution of the display area DA. For example, as shown in FIG. 5, one groove SPR may be defined in the pixel-defining layer PDL between the pixel electrodes PE. As shown in FIG. 6, the groove SPR may be located within the third width W3 of the black matrix BM. According to an embodiment, the groove SPR may be located to approximately correspond to a center of the black matrix BM.

In the display area DA, the plurality of pixels PX may be arranged in any one of various shapes, such as a pentile matrix structure or a pentile structure, a stripe structure, an S-stripe structure, a mosaic structure, and a delta structure. In the present specification, an arrangement of pixels may denote an arrangement of display elements or an arrangement of emission areas.

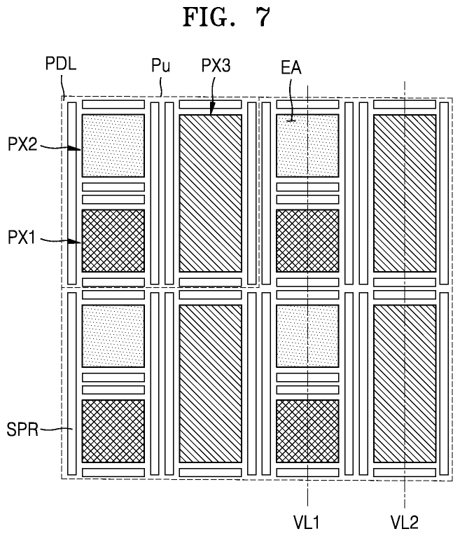

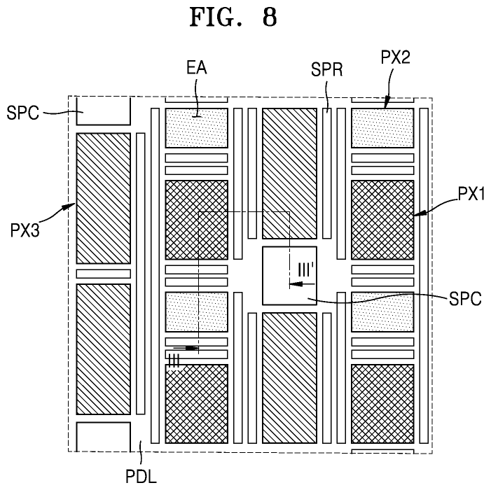

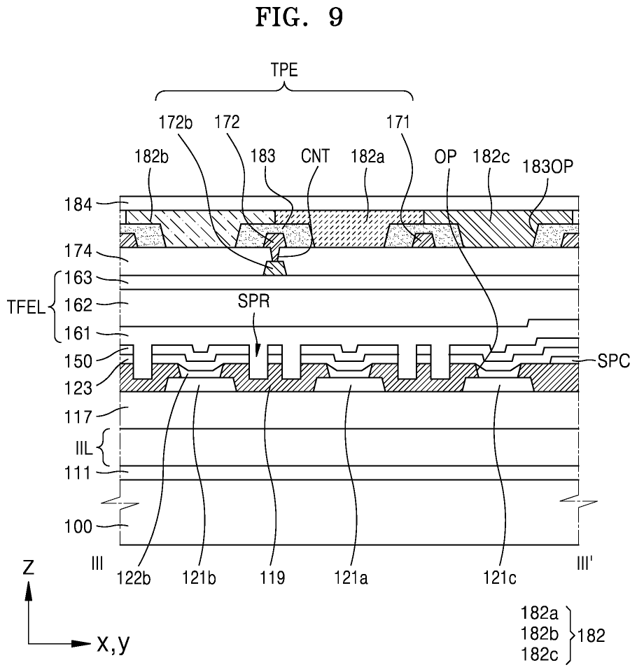

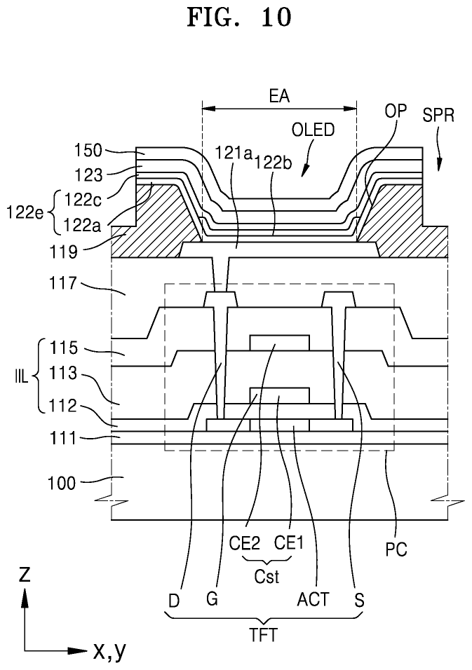

FIGS. 7 and 8 are plan views of portions of display areas DA, according to embodiments. FIG. 9 is a cross-sectional view of the display area DA taken along line III-III′ of FIG. 8. FIG. 10 is a view of a first pixel PX1 of FIG. 9.

Referring to FIG. 7, each of unit pixels PU may be repeatedly arranged in the x-axis direction and y-axis direction in the display area DA of the substrate 100. Each of the unit pixels PU may include the first pixel PX1, a second pixel PX2, and a third pixel PX3. According to an embodiment, the first pixel PX1 may be a red pixel emitting a red color, the second pixel PX2 may be a green pixel emitting a green color, and the third pixel PX3 may be a blue pixel emitting a blue color.

According to an embodiment, the plurality of pixels PX may be arranged in an S-stripe structure. The emission area EA of the first pixel PX1 and the emission area EA of the second pixel PX2 may be alternately arranged in the y-axis direction along a first virtual line VL1, and the emission area EA of the third pixel PX3 may be repeatedly arranged in the y-axis direction on a column adjacent to a column where the first pixel PX1 and the second pixel PX2 are arranged, along a second virtual line VL2. A length of the emission area EA of the third pixel PX3 in the y-axis direction may be equal to or greater than a sum of a length of the emission area EA of the first pixel PX1 in the y-axis direction and a length of the emission area EA of the second pixel PX2 in the y-axis direction.

The emission area EA of the first pixel PX1, the emission area EA of the second pixel PX2, and the emission area EA of the third pixel PX3 may have different areas. According to an embodiment, the emission area EA of the third pixel PX3 may have a greater area than the emission area EA of the first pixel PX1. Also, the emission area EA of the third pixel PX3 may have a greater area than the emission area EA of the second pixel PX2. As shown in FIG. 7, the emission area EA of the first pixel PX1 may be the same as the emission area EA of the second pixel PX2, or as shown in FIG. 8, the emission area EA of the first pixel PX1 may have a greater area than the emission area EA of the second pixel PX2. According to another embodiment, the emission area EA of the third pixel PX3 may have a same area as the emission area EA of the first pixel PX1. However, the disclosure is not limited thereto. Various embodiments are possible, for example, the emission area EA of the first pixel PX1 may be greater than the emission area EA of the second pixel PX2 and the emission area EA of the third pixel PX3.

The emission area EA may have a shape of a polygon, such as a quadrangle or an octagon, a circle, or an oval, and may include a shape in which corners (vertexes) of a polygon is rounded.

The groove SPR may be defined in the pixel-defining layer PDL surrounding the emission areas EA. Two grooves SPR may be located between the adjacent emission areas EA. The grooves SPR may be located correspondingly within a width of a black matrix 183.

According to an embodiment, as shown in FIG. 8, a spacer SPC may be arranged in a partial region between the emission areas EA. The spacer SPC may be arranged between the emission areas EA of the third pixels PX3 adjacent to each other in the y-axis direction. A single layer or a multi-layer of the spacer SPC may be arranged on the pixel-defining layer PDL. Furthermore, each length of the two adjacent grooves SPR may be different each other in a plan view.

Hereinafter, a stack structure of elements included in the display panel 10 will be described with reference to FIG. 9. The display panel 10 may include the substrate 100, a buffer layer 111, an inorganic insulating layer IIL, and a display element. The thin-film encapsulation layer TFEL, a touch screen layer, and the optical functional layer may be further stacked on the display element, as encapsulation members.

The buffer layer 111, the inorganic insulating layer IIL, and a planarization layer 117 may be sequentially stacked on the substrate 100 in a z-axis direction. The planarization layer 117 may include an organic material or an inorganic material, and may have a single-layer structure or a multi-layer structure. As shown in FIG. 10, a pixel circuit PC may be arranged between the buffer layer 111 and the planarization layer 117. The pixel circuit PC may include a thin-film transistor TFT and a capacitor Cst. The thin-film transistor TFT may include a semiconductor layer ACT, a gate electrode G, a source electrode S, and a drain electrode D. The capacitor Cst may include a lower electrode CE1 and an upper electrode CE2.

The semiconductor layer ACT may be disposed on the buffer layer 111. The semiconductor layer ACT may include amorphous silicon, polycrystalline silicon, or an organic semiconductor material, such as an oxide semiconductor. The semiconductor layer ACT may include a channel region, and a source region and a drain region where impurities are doped. A first insulating layer 112 may be disposed on the semiconductor layer ACT, and the gate electrode G overlapping the semiconductor layer ACT may be disposed on the first insulating layer 112. A second insulating layer 113 may be disposed on the gate electrode G, and the upper electrode CE2 of the capacitor Cst may be disposed on the second insulating layer 113. The upper electrode CE2 may overlap the gate electrode G therebelow. The gate electrode G and the upper electrode CE2, which overlap with the second insulating layer 113 therebetween, may form the capacitor Cst. The gate electrode G may be the lower electrode CE1 of the capacitor Cst. A third insulating layer 115 may be disposed on the capacitor Cst, and the source electrode S and the drain electrode D may be disposed on the third insulating layer 115. The first insulating layer 112, the second insulating layer 113, and the third insulating layer 115 may be collectively referred to as the inorganic insulating layer IIL.

The planarization layer 117 may be disposed on the source electrode S and drain electrode D, and the organic light-emitting diodes OLED that are display elements of the pixels PX may be disposed on the planarization layer 117. The organic light-emitting diode OLED may include a pixel electrode, an opposing electrode 123, and an intermediate layer between the pixel electrode and the opposing electrode 123.

A pixel electrode 121a of the first pixel PX1, a pixel electrode 121b of the second pixel PX2, and a pixel electrode 121c of the third pixel PX3 may be disposed on the planarization layer 117.

A pixel-defining layer 119 may be disposed on the planarization layer 117. The pixel-defining layer 119 may cover edges of the pixel electrodes 121a through 121c of the first through third pixels PX1 through PX3, and include the openings OP exposing portions of the pixel electrodes 121a through 121c. A size and shape of the emission area EA of the organic light-emitting diode OLED, i.e., of the pixel PX, may be defined by the opening OP.

The pixel-defining layer 119 may include a transparent insulating material or an opaque insulating material. According to an embodiment, the pixel-defining layer 119 may include an organic insulating material, such as polyimide, polyamide, acryl resin, benzo cyclobutene, hexamethyldisiloxane (HMDSO), or phenol resin. According to another embodiment, the pixel-defining layer 119 may include an inorganic insulating material, such as silicon nitride or silicon oxide, or may include an organic insulating material and an inorganic insulating material. The groove SPR may be defined in the pixel-defining layer 119.

The spacer SPC may be further disposed on the pixel-defining layer 119. According to an embodiment, the spacer SPC may include a material same as the pixel-defining layer 119. In this case, the pixel-defining layer 119 and the spacer SPC may be formed together during a mask process using a half-tone mask, and the spacer SPC may protrude from the pixel-defining layer 119 in the z-axis direction. According to another embodiment, the spacer SPC may include a different material from the pixel-defining layer 119. In this case, the spacer SPC may include insulating patterns of island shapes arranged on the pixel-defining layer 119 at certain intervals. The spacer SPC may be disposed on the pixel-defining layer 119 where the groove SPR is not defined. A region of the pixel-defining layer 119 where the groove SPR is defined may not include the spacer SPC.

As shown in FIG. 10, the intermediate layer may include an emission layer 122b and an organic functional layer 122e on and/or below the emission layer 122b.

The emission layers 122b may be arranged to correspond to the pixel electrodes 121a through 121c inside the openings OP of the pixel-defining layer 119. The emission layer 122b may include a high-molecular or a low-molecular material, and emit red, green, blue, or white light.

The organic functional layer 122e may include a first functional layer 122a and/or a second functional layer 122c. The first functional layer 122a or the second functional layer 122c may be omitted.

The first functional layer 122a may be disposed below the emission layer 122b. The first functional layer 122a may be a single layer or multi-layer including an organic material. The first functional layer 122a may be a hole transport layer (HTL) having a single-layer structure. Alternatively, the first functional layer 122a may include a hole injection layer (HIL) and an HTL. The first functional layer 122a may be integrally formed to correspond to the organic light-emitting diodes OLED included in the display area DA.

The second functional layer 122c may be disposed on the emission layer 122b. The second functional layer 122c may be a single layer or multi-layer including an organic material. The second functional layer 122c may include an electron transport layer (ETL) and/or an electron injection layer (EIL). The second functional layer 122c may be integrally formed to correspond to the organic light-emitting diodes OLED included in the display area DA.

The opposing electrode 123 may be disposed on the emission layer 122b.

Although not illustrated, according to an embodiment, the intermediate layer may include two or more emitting units sequentially stacked between the pixel electrode and the opposing electrode 123, and a charge generation layer (CGL) provided between the two emitting units. When the intermediate layer includes the emitting units and the CGL, the organic light-emitting diode OLED may be a tandem light-emitting element. The organic light-emitting diode OLED may have a stack structure of a plurality of emitting units, and thus have improved color purity and light-emitting efficiency.

One emitting unit may include an emission layer, and a first functional layer and a second functional layer respectively below and on the emission layer. The CGL may include a negative CGL and a positive CGL. The light-emitting efficiency of the organic light-emitting diode OLED that is the tandem light-emitting element including the plurality of emission layers may be further increased by the negative CGL and the positive CGL. The negative CGL may be an n-type CGL. The negative CGL may supply electrons. The negative CGL may include a host and a dopant. The host may include an organic material. The dopant may include a metal material. The positive CGL may be a p-type CGL. The positive CGL may supply holes. The positive CGL may include a host and a dopant. The host may include an organic material. The dopant may include a metal material.

An upper layer 150 including an organic material may be disposed on the opposing electrode 123. The upper layer 150 may be a layer provided to protect the opposing electrode 123 while increasing light-extracting efficiency. The upper layer 150 may include lithium fluoride (LiF). Alternatively, the upper layer 150 may further include an inorganic insulating material, such as silicon oxide (SiOₓ) or a silicon nitride (SiNₓ).

The groove SPR may be defined in the pixel-defining layer 119 by removing a portion of the pixel-defining layer 119. When the portion of the pixel-defining layer 119 is removed, the first functional layer 122a, the second functional layer 122c, the opposing electrode 123, and the upper layer 150 disposed thereon may be removed together. Accordingly, a hole having a shape of the groove SPR may be formed in each of regions of the first functional layer 122a, the second functional layer 122c, the opposing electrode 123, and the upper layer 150, which correspond to the groove SPR. When the organic light-emitting diode OLED is a tandem light-emitting element, a hole having a shape of the groove SPR may be formed in a region of the CGL, which corresponds to the groove SPR.

The display elements may be covered by the thin-film encapsulation layer TFEL. The thin-film encapsulation layer TFEL may be embedded in the groove SPR of the pixel-defining layer 119. According to some embodiments, the thin-film encapsulation layer TFEL may include at least one inorganic encapsulation layer and at least one organic encapsulation layer. According to an embodiment, the thin-film encapsulation layer TFEL may include first and second inorganic encapsulation layers 161 and 163, and an organic encapsulation layer 162 therebetween. The first inorganic encapsulation layer 161 may be embedded in the groove SPR of the pixel-defining layer 119.

The touch screen layer may be disposed on the second inorganic encapsulation layer 163. The touch screen layer may obtain coordinate information according to an external input, for example, a touch event. The touch screen layer may detect the external input through self-capacitance method or a mutual capacitance method. The touch screen layer may include a touch electrodes TPE and wires connected to the touch electrodes TPE. The touch electrodes TPE may include first touch electrodes 171 and second touch electrodes 172. The first touch electrodes 171 may be connected to each other by connection electrodes arranged on a same layer. The second touch electrodes 172 may be connected to connection electrodes 172b arranged on a different layer, through a contact hole CNT penetrating an insulating layer 174.

The optical functional layer may include a color filter 182, the black matrix 183, and an overcoated layer 184. The black matrix 183 may cover the first touch electrodes 171 and the second touch electrodes 172. The black matrix 183 may be located to correspond to the pixel-defining layer 119. The overcoated layer 184 may include an organic material such as resin, and the organic material may be transparent.

The groove SPR of the pixel-defining layer 119 and the holes of the first functional layer 122a, second functional layer 122c, CGL, opposing electrode 123, and upper layer 150, which correspond to the groove SPR, may be covered by the black matrix 183 and not be exposed outside the black matrix 183. Accordingly, color separation phenomenon which occurs when external light is introduced may be reduced.

The color filter 182 may include a first color filter 182a configured to selectively transmit only red light, a second color filter 182b configured to selectively transmit only green light, and a third color filter 182c configured to selectively transmit only blue light. The first color filter 182a may be arranged to correspond to the emission area EA of the first pixel PX1, the second color filter 182b may be arranged to correspond to the emission area EA of the second pixel PX2, and the third color filter 182c may be arranged to correspond to the emission area EA of the third pixel PX3. The first color filter 182a, the second color filter 182b, and the third color filter 182c may be adjacent to each other. Each of the first color filter 182a, the second color filter 182b, and the third color filter 182c may have an independent pattern structure. Each of the first color filter 182a, the second color filter 182b, and the third color filter 182c may be arranged in an opening 1830P of the black matrix 183. The first color filter 182a, the second color filter 182b, and the third color filter 182c may each partially overlap the pixel-defining layer 119.

A cover window (not shown) may be disposed on the display panel 10 to protect the display panel 10.

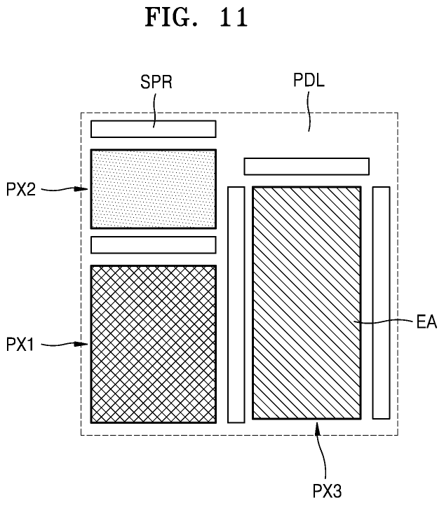

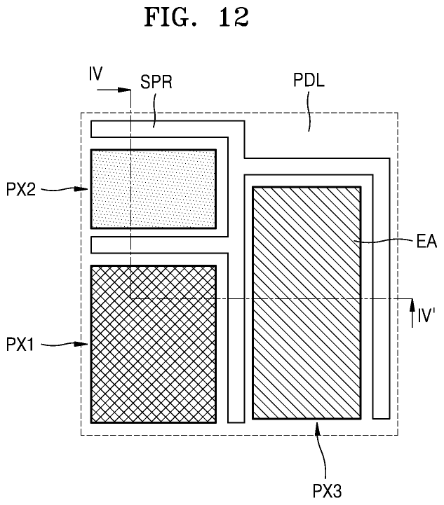

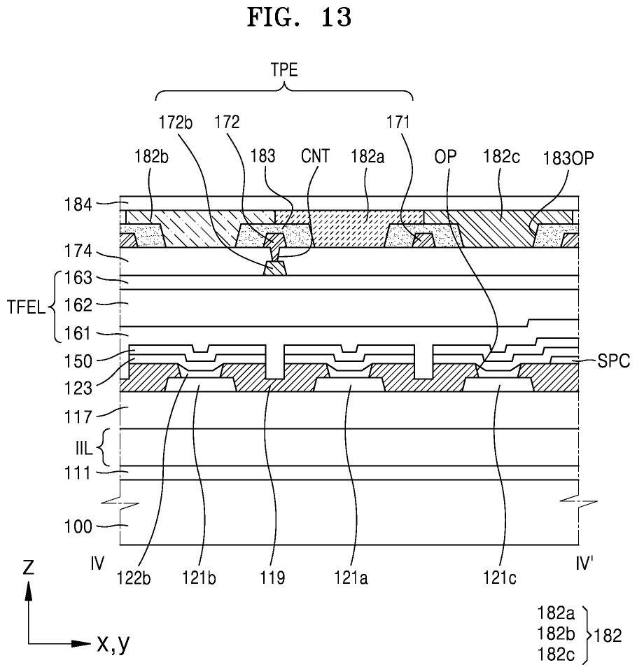

FIGS. 11 and 12 are plan views of a portion of a display area DA, according to embodiments. FIG. 13 is a cross-sectional view of the display area DA taken along line IV-IV′ of FIG. 12.

As shown in FIGS. 11 and 12, one groove SPR may be located between the adjacent emission areas EA. According to an embodiment, as shown in FIG. 11, the groove SPR may have a straight-line shape extending in the x-axis direction or the y-axis direction. According to another embodiment, as shown in FIG. 12, the groove SPR may extend along an edge of the emission area EA and may be curved while partially surrounding the emission area EA. The groove SPR may include a portion extending in the x-axis direction and a portion extending in the y-axis direction. In FIG. 12, the groove SPR has a straight-line shape, but according to another embodiment, may have a curved shape according to a shape of the emission area EA. As shown in FIG. 13, the groove SPR may be located to correspond to a center of the black matrix 183.

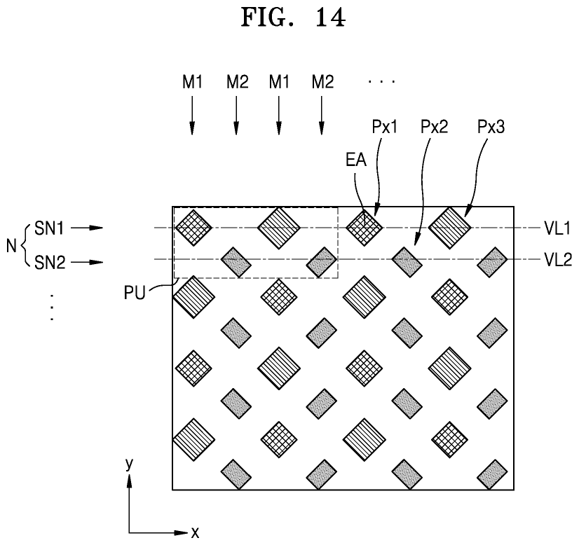

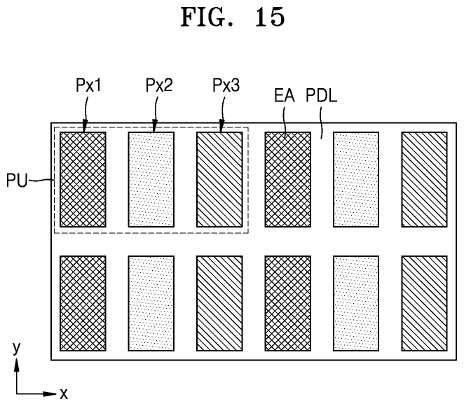

FIGS. 14 and 15 are views showing arrangements of the emission areas EA of the plurality of pixels PX, according to embodiments.

As shown in FIG. 14, according to an embodiment, the plurality of pixels PX may be arranged in a pentile structure. Each of the unit pixels PU may include the first pixel PX1, a pair of the second pixels PX2, and the third pixel PX3. The emission area EA of the first pixel PX1 and the emission area EA of the third pixel PX3 may be alternately arranged in the y-axis direction in a first column M1. The emission areas EA of the second pixels PX2 may be repeatedly arranged in the y-axis direction in a second column M2. The first column M1 and the second column M2 may alternate in the x-axis direction, and an arrangement of the emission area EA of the first pixel PX1 and the emission area EA of the third pixel PX3 may be opposite in the adjacent first columns M1.

The emission area EA of the first pixel PX1 and the emission area EA of the third pixel PX3 may be alternately arranged in the x-axis direction along the first virtual line VL1 in a first sub-row SN1 of each row N, and the emission areas EA of the second pixels PX2 may be repeatedly arranged in the x-axis direction along the second virtual line VL2 in a second sub-row SN2.

As shown in FIG. 15, according to an embodiment, the plurality of pixels PX may be arranged in a stripe structure. In the stripe structure, the emission areas EA of the first pixel PX1, second pixel PX2, and third pixel PX3 may be arranged in parallel to each other in a certain direction.

The groove SPR and/or the spacer SPC described above may be located in the pixel-defining layer PDL around the emission area EA shown in FIGS. 14 and 15. As shown in FIGS. 2-13, the groove SPR may be a concave portion formed in the pixel-defining layer PDL by etching the pixel-defining layer PDL. The spacer SPC may be a protruding portion formed as a portion of the pixel-defining layer PDL protrudes, and may be an insulating pattern arranged on the pixel-defining layer PDL separately from the pixel-defining layer PDL. According to an embodiment, the groove SPR may not be located in a region of the pixel-defining layer PDL where the spacer SPC is arranged.

According to embodiments, display quality may be improved by arranging a plurality of grooves of a pixel-defining layer around a pixel electrode and completely covering the groove by a black matrix of an optical functional layer. Two or more grooves may be arranged in parallel to each other between the pixel electrodes. According to an embodiment, as shown in FIGS. 2, 5, 7, 8, and 11, the plurality of grooves may be spaced apart from each other along an edge of the pixel electrode. According to another embodiment, as shown in FIG. 12, the groove may extend along the edge of pixel electrode and surround a portion of the pixel electrode.

A display device according to embodiments may be implemented as an electronic device, such as a smart phone, a mobile phone, a smart watch, a navigation device, a game device, a TV, a head unit for a vehicle, a notebook computer, a laptop computer, a tablet computer, a personal media player (PMP), or a personal digital assistant (PDA). Also, the electronic device may be a flexible device.

According to embodiments, a display device in which display quality is improved may be provided by locating a groove of a pixel-defining layer within a width of a black matrix of an optical functional layer. Obviously, the scope of the disclosure is not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
a pixel electrode disposed on the substrate;
a pixel-defining layer disposed between the pixel electrodes, wherein an opening corresponding to a portion of the pixel electrode is defined in the pixel-defining layer and at least one groove is defined around the pixel electrode;
a color filter arranged to correspond to the opening of the pixel-defining layer; and
a black matrix arranged to correspond to the pixel-defining layer,
wherein the groove in the pixel-defining layer is located within a width of the black matrix.

2. The display panel of claim 1, further comprising:
an opposing electrode facing the pixel electrode; and
an intermediate layer disposed between the pixel electrode and the opposing electrode,
wherein a hole corresponding to the groove in the pixel-defining layer is defined in the opposing electrode and the intermediate layer.

3. The display panel of claim 2, wherein the intermediate layer includes an organic functional layer and a charge generation layer.

4. The display panel of claim 1, wherein an opening corresponding to the opening of the pixel-defining layer is defined in the black matrix,
wherein an area of the opening of the black matrix is greater than an area of the opening of the pixel-defining layer.

5. The display panel of claim 1, wherein there is a plurality of grooves in the pixel-defining layer, and the plurality of grooves are arranged in parallel to each other.

6. The display panel of claim 1, wherein there is a plurality of grooves in the pixel-defining layer, and
the plurality of grooves are spaced apart from each other along an edge of the pixel electrode.

7. The display panel of claim 1, wherein the groove in the pixel-defining layer extends along an edge of the pixel electrode and surrounds a portion of the pixel electrode.

8. The display panel of claim 2, further comprising an upper layer disposed on the opposing electrode,
wherein a hole corresponding to the groove in the pixel-defining layer is defined in the upper layer.

9. The display panel of claim 1, further comprising a spacer disposed on the pixel-defining layer,
wherein the groove is not located in the pixel-defining layer where the spacer is disposed.

10. The display panel of claim 2, further comprising a thin-film encapsulation layer disposed between the opposing electrode and the color filter,
wherein the thin-film encapsulation layer covers the groove in the pixel-defining layer.

11. The display panel of claim 10, further comprising a touch screen disposed between the thin-film encapsulation layer and the color filter,
wherein a touch electrode of the touch screen layer is covered by the black matrix.

12. A display panel comprising:
a substrate including a display area, in which an emission area and a non-emission area surrounding the emission area are defined;
a pixel-defining layer arranged to correspond to the non-emission area in which a groove is defined, wherein a first opening corresponding to the emission area is defined in the pixel-defining layer;
a black matrix arranged to corresponding to the non-emission area, wherein a second opening corresponding to the emission area is defined in the black matrix and has a greater area than the first opening; and
a color filter arranged in the second opening of the black matrix,
wherein an entirety of the black matrix covers the groove in the pixel-defining layer.

13. The display panel of claim 12, further comprising:
a plurality of pixel electrodes, each of the plurality of pixel electrodes arranged to a corresponding emission area;
an opposing electrode facing the plurality of pixel electrodes; and
an intermediate layer between the plurality of pixel electrodes and the opposing electrode,
wherein the opposing electrode and the intermediate layer each include a hole corresponding to the groove in the pixel-defining layer.

14. The display panel of claim 13, wherein the intermediate layer includes an organic functional layer and a charge generation layer.

15. The display panel of claim 12, wherein there is a plurality of grooves in the pixel-defining layer, and the plurality of grooves are arranged in parallel to each other.

16. The display panel of claim 13, wherein there is a plurality of grooves in the pixel-defining layer, and the plurality of grooves are spaced apart from each other along edges of the plurality of pixel electrodes.

17. The display panel of claim 13, wherein the groove in the pixel-defining layer extends along edges of the plurality of pixel electrodes and surrounds portions of the plurality of pixel electrodes.

18. The display panel of claim 13, further comprising an upper layer disposed on the opposing electrode,
wherein the upper layer includes a hole corresponding to the groove in the pixel-defining layer.

19. The display panel of claim 12, further comprising a spacer disposed on the pixel-defining layer,
wherein the groove is not located in the pixel-defining layer where the spacer is disposed.

20. The display panel of claim 13, further comprising a thin-film encapsulation layer disposed between the opposing electrode and the color filter,
wherein the thin-film encapsulation layer covers the groove in the pixel-defining layer.
